(19) United States
(12) Patent Application Publication
(10) Pub. No.: US 2026/0291170 A1
(43) Pub. Date: Sep. 24, 2026

(54) Laser Unit for a Rotary Laser and Rotary Laser with the Laser Unit

(71) Applicant: Robert Bosch GmbH, Stuttgart (DE)

(72) Inventors: Tobias Zibold, Stuttgart (DE); Ben William Carabelli, Leinfelden-Echterdingen (DE); Keith Lam, Warfield (GB); Markus Hahl, Korntal-Muenchingen (DE); Tobias Roehm, Wildberg-Sulz (DE); Wei Loon Peh, Georgetown (MY)

(21) Appl. No.: 19/567,182

(22) Filed: Mar. 15, 2026

(30) Foreign Application Priority Data
Mar. 20, 2025 (DE) 10 2025 110 724.6

(51) Int. Cl. H01S 5/026; H01S 5/00; H01S 5/02315; H01S 5/062

(52) U.S. Cl. CPC H01S 5/0264; H01S 5/0014; H01S 5/02315; H01S 5/062

(57) ABSTRACT

A laser unit for a rotary laser includes a laser module housing, in which a laser diode for generating a laser beam and a collimating lens for collimating the laser beam are arranged. The laser diode is associated with a monitor diode. An automatic power control circuit is provided for automatically controlling a laser power of the laser diode based on a measurement of the laser power by the monitor diode. A photodiode is provided for a laser power measurement independent of the monitor diode.

This application claims priority under 35 U.S.C. § 119 to patent application no. DE 10 2025 110 724.6, filed on Mar. 20, 2025 in Germany, the disclosure of which is incorporated herein by reference in its entirety.

### BACKGROUND

The present disclosure relates to a laser unit for a rotary laser, with a laser module housing, in which a laser diode for generating a laser beam and a collimating lens for collimating the laser beam are arranged, wherein the laser diode is associated with a monitor diode, and wherein an automatic power control circuit for automatically controlling the laser power of the laser diode, based on a measurement of the laser power by the monitor diode, is provided.

A rotary laser with such a laser unit is known from the prior art. The laser unit comprises a laser module housing, in which a laser diode for generating a laser beam and a collimating lens for collimating the laser beam are arranged. The laser diode is associated with a monitor diode. Furthermore, an automatic power control circuit for automatically controlling a laser power of the laser diode, based on a measurement of the laser power by the monitor diode, is provided.

### SUMMARY

The disclosure relates to a laser unit for a rotary laser, with a laser module housing, in which a laser diode for generating a laser beam and a collimating lens for collimating the laser beam are arranged, wherein the laser diode is associated with a monitor diode, and wherein an automatic power control circuit for automatically controlling the laser power of the laser diode, based on a measurement of the laser power by the monitor diode, is provided. A photodiode is provided for a laser power measurement independent of the monitor diode.

The disclosure thus enables a laser unit for a rotary laser to be provided, in which safe and reliable operation can be achieved by the photodiode measuring the laser power independent of the monitor diode.

The monitor diode is preferably a monitor diode integrated into the laser diode.

By integrating the monitor diode into the laser diode, a compact design of the laser unit can be achieved.

Preferably, the photodiode is associated with a protective circuit, which is configured to disable the laser diode via a control line by interrupting the power supply to the laser diode, or to disable the automatic power control circuit via a control line if the laser power measured by the photodiode exceeds a specified laser power limit.

Thus, safe operation of the laser unit can be achieved in a simple and straightforward manner.

The laser diode is preferably associated with a laser diode holder, the photodiode is associated with a photodiode holder, and/or the collimating lens is associated with a collimating lens holder.

Thus, a safe and robust arrangement of the laser diode, the photodiode and/or the collimating lens in the laser unit may be achieved.

Preferably, the laser module housing comprises a receptacle forming the laser diode holder for receiving the laser diode and the photodiode holder for receiving the photodiode, wherein a beam splitter is arranged in the receptacle, and wherein the laser diode is arranged on an incoming side of the beam splitter, and the photodiode is arranged on an outgoing side of the beam splitter.

Thus, a simple and straightforward provision of the laser diode holder and the photodiode holder as well as a compact construction of the laser unit can be achieved by use of the beam splitter.

Preferably, the collimating lens is arranged on a further outgoing side of the beam splitter.

A suitable arrangement of the collimating lens can thus be achieved in a simple manner.

According to one embodiment, the laser module housing comprises a first receptacle configured as a photodiode holder for receiving the photodiode and a second receptacle configured as a laser diode holder for receiving the laser diode, wherein the first receptacle is arranged perpendicularly to the second receptacle, and the second receptacle is arranged collinearly to an optical axis of the collimating lens.

Thus, an alternative configuration of the photodiode holder and the laser diode holder can be easily and straightforwardly achieved.

Preferably, the first receptacle is arranged spaced apart from the second receptacle along a longitudinal extension of the laser module housing.

Thus, a suitable arrangement of the second receptacle relative to the first receptacle may be achieved in a straightforward manner, through which an independent measurement of the laser power may be facilitated by the photodiode.

Preferably, the first receptacle is arranged along a direction of greatest divergence of an emission characteristic of the laser diode.

Safe and reliable operation of the laser unit can thus be achieved.

In accordance with one embodiment, a circuit board is provided, on which the laser diode and the photodiode are arranged, wherein the circuit board and the photodiode holder are arranged on the laser diode holder.

Thus, a further configuration of the photodiode holder and the laser diode holder can be easily and straightforwardly achieved.

Preferably, the circuit board comprises at least a first circuit board section and a second circuit board section arranged perpendicularly or in parallel to the first circuit board section, wherein the laser diode is arranged on the first circuit board section, and the photodiode is arranged on the second circuit board section.

Thus, a safe and reliable arrangement of the photodiode and the laser diode on the circuit board can be achieved.

Advantageously, the circuit board is embodied as a flexible circuit board.

Thus, the perpendicular or parallel arrangement of the second circuit board section relative to the first circuit board section of the circuit board may be achieved in a simple manner.

Preferably, the laser module housing comprises a receptacle forming the collimating lens holder.

Thus, an alternative configuration of the collimating lens holder can be easily and straightforwardly achieved.

Preferably, a distance between the laser diode and the collimating lens is variable, wherein the laser diode holder of the laser diode is slidably arranged in a receptacle of the laser module housing along the longitudinal extension of the laser module housing, and/or the collimating lens holder of the collimating lens is slidably arranged in an interior receptacle of the laser module housing along the longitudinal extension of the laser module housing, wherein the interior receptacle is arranged collinearly to an optical axis of the collimating lens.

Thus, the distance between the laser diode and the collimating lens can be easily adjusted.

Moreover, the present disclosure relates to a rotary laser with the laser unit described.

The disclosure thus enables a rotary laser with a laser unit to be provided, in which safe and reliable operation of the laser unit and thus the rotary laser can be achieved by the photodiode measuring the laser power independent of the monitor diode.

### BRIEF DESCRIPTION OF THE DRAWINGS

The disclosure is explained in more detail in the following description with reference to the exemplary embodiments shown in the drawings. They show:

FIG. 1 a perspective view of a rotary laser with a laser unit according to the disclosure,

FIG. 2 a schematic view of the laser unit of FIG. 1,

FIG. 3 a schematic view of a circuit board associated with the laser unit of FIG. 1 and FIG. 2,

FIG. 4 a schematic view of a first circuit associated with the laser unit of FIG. 1,

FIG. 5 a schematic view of an alternative configuration of the laser unit of FIG. 1,

FIG. 6 an exploded perspective view of a further configuration of the laser unit of FIG. 1,

FIG. 7 a cross-sectional view of the laser unit of FIG. 6,

FIG. 8 a schematic view of a second circuit associated with the laser unit of FIG. 1,

FIG. 9 a perspective view of a circuit board associated with the laser unit of FIG. 6 and FIG. 7 with a laser diode and a photodiode,

FIG. 10 a view of the circuit board with the laser diode and the photodiode of FIG. 9, viewed in the direction of an arrow 901 of FIG. 9,

FIG. 11 a schematic view of an alternative configuration of the laser unit of FIG. 1,

FIG. 12 a perspective view of an alternative circuit board associated with the laser unit of FIG. 6 and FIG. 7 with a laser diode and a photodiode,

FIG. 13 a top view of a first side of the circuit board of FIG. 12,

FIG. 14 a top view of a second side of the circuit board of FIG. 12 and FIG. 13,

FIG. 15 a perspective view of the circuit board of FIG. 12 to FIG. 14 in the installed state with fixing elements,

FIG. 16 a perspective view of the laser unit of FIG. 6 and FIG. 7 with the circuit board of FIG. 12 to FIG. 15,

FIG. 17 a perspective view of the laser unit of FIG. 16 with a shielding element arranged on the circuit board,

FIG. 18 a perspective view of the laser unit of FIG. 17 with the circuit board and a perspective view of the shielding element, and

FIG. 19 a cross-sectional view of the laser unit of FIG. 18.

### DETAILED DESCRIPTION

Elements with the same or a comparable function are provided with the same reference signs in the figures and are described in detail only once.

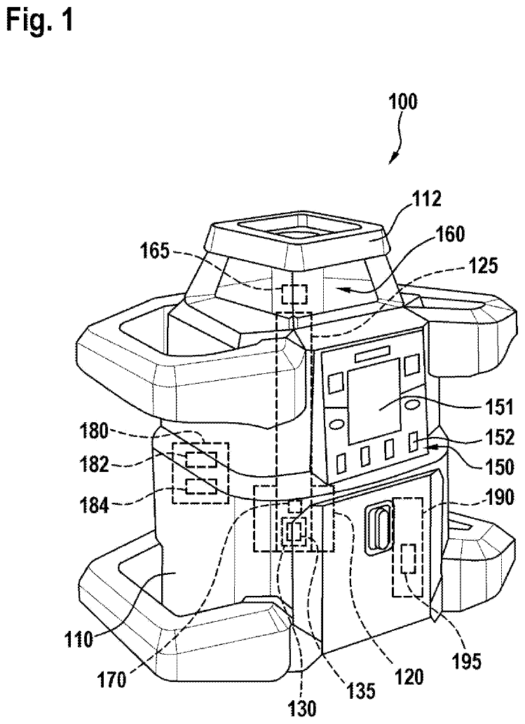

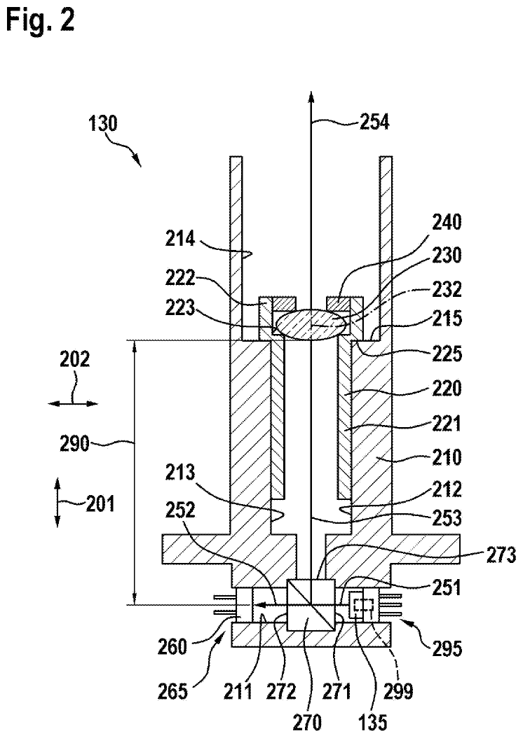

FIG. 1 illustrates an exemplary rotary laser 100 with a laser housing 110, in which a laser unit 130 with a laser diode 135 for generating a laser beam (251 in FIG. 2) is arranged. A “rotary laser” may also be understood in the context of the present disclosure to mean a construction laser or a leveling laser. Furthermore, a drive unit 120 for rotationally driving a drive shaft 125 is arranged in the laser housing 110, for example.

The laser unit 130 is illustratively arranged on the drive shaft 125 such that rotation of the drive shaft 125 rotates the laser beam (251 in FIG. 2) generated by the laser unit 130 in an associated plane. To this end, the drive shaft 125 is preferably associated with a rotary head 160 with a beam deflector 165. The beam deflector 165 is preferably configured to deflect the laser beam (254 in FIG. 2), as a result of which the laser beam (254 in FIG. 2) projects the associated plane. Alternatively, the beam diverter 165 is configured as a beam splitter, thereby emitting a laser beam perpendicular to the laser plane along the laser axis (254 in FIG. 2) in addition to the projected plane. Depending on the design of the rotary laser 100, the projected plane may be horizontal, vertical, or, e.g., at a defined tilt angle with respect to the earth's surface. The drive unit 120 is preferably configured as an electric motor.

Moreover, an electronic unit 190 with a control and monitoring device 195 is preferably arranged in the laser housing 110. The control and monitoring device 195 is preferably configured to control the laser power of the laser unit 130 depending on a mode of operation. A rotational speed of the drive shaft 125 of the drive unit 120 is thus controlled or regulated. Preferably, a determination unit 170 is associated with the drive shaft 125 for this purpose.

According to one embodiment, the laser housing 110 is associated with a protective cage 112 associated with the rotary head 160 to protect against the rotary head 160 striking something.

The electronic unit 190 is preferably associated with an operating unit 150 with a display 151 and/or an input unit 152. The operating unit 150 is preferably connected to the electronic unit 190, in particular to the control and monitoring device 195, for control or regulation. The input unit 152 comprises at least one keypad. In a minimized configuration, the input unit 152 comprises only an on/off switch, in particular an on/off button. Alternatively, it is also conceivable that the input unit 152 comprises a control dial, a touch screen, a slider, a remote control, or the like. For example, via the input unit 152, a user may enter a rotational speed for the drive shaft 125. Alternatively, the rotational speed of the laser unit 130 is automatically controllable in one mode of operation.

Preferably, the rotary laser 100 comprises a leveling unit 180. The leveling unit 180 preferably comprises at least one tilt sensor 184 configured to determine a tilt of the rotary head 160, in particular of the beam diverter 165, and/or of the laser unit 130, relative to a predetermined, preferably horizontal direction or to a vertical direction. Moreover, the leveling unit 180 preferably comprises at least one tilt adjustment motor 182 configured to align the rotary head 160, in particular the beam diverter 165, and/or the laser unit 130, depending on a position determined by the at least one tilt sensor 184, preferably a tilt of the laser unit 130 and/or the rotary head 160, preferably in the vertical direction.

FIG. 2 illustrates an exemplary configuration of the laser unit 130 of the rotary laser 100 of FIG. 1. The laser unit 130 is illustratively associated with a laser module housing 210, in which the laser diode 135 is arranged to generate a laser beam 251 as well as a collimating lens 230 for collimating the laser beam 251. The laser diode 135 is associated with a monitor diode 299. The monitor diode 299 is configured to measure a laser power associated with the laser diode 135. According to one embodiment, the monitor diode 299 is a monitor diode integrated into the laser diode 135. Such a laser diode 135 with an integrated monitor diode 299 is sufficiently known from the prior art, so a more detailed description is omitted for the purpose of brevity in the description.

According to the present disclosure, the laser unit 130 comprises a photodiode 260, which is provided for a laser power measurement independent of the monitor diode 299.

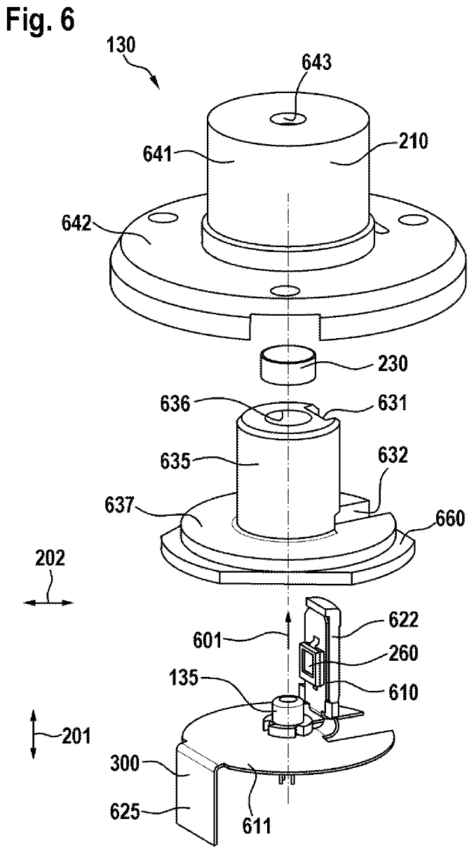

Preferably, the laser diode 135 is associated with a laser diode holder 295 (660 in FIG. 6), the photodiode 260 is associated with a photodiode holder 265 (622 in FIG. 6), and/or the collimating lens 230 is associated with a collimating lens holder 220. The collimating lens holder 220 is arranged in an interior receptacle 212 of the laser module housing 210. The interior receptacle 212 is aligned along a longitudinal extension 201 of the preferably cylindrical laser module housing 210. Furthermore, the interior receptacle 212 is preferably arranged collinearly to an optical axis 232 of the collimating lens 230.

Preferably, a distance 290 between the laser diode 135 and the collimating lens 230 is variable. For this purpose, the collimating lens holder 220 is preferably slidably arranged along the longitudinal extension 201 of the laser module housing 210 in the interior receptacle 212. Preferably, the collimating lens 230 is associated with an aperture 240.

Illustratively, the interior receptacle 212 comprises a lower receptacle region 213, the bottom surface 215 which flares out into an upper receptacle region 214. A section 221 of the collimating lens holder 220, shown at the bottom for illustrative purposes, is arranged in the lower receptacle region 213 of the interior receptacle 212 as an example, and a section 222 of the collimating lens holder 220, shown at the top for illustrative purposes, is preferably arranged in the upper receptacle region 214 of the interior receptacle 212. An underside 225 of the upper section 222 of the collimating lens holder 220 is illustratively arranged at the bottom surface 215 of the upper receptacle region 214. The upper section 222 of the collimating lens holder 220, by way of example, comprises a lens receptacle 223, in which the collimating lens 230 is arranged.

The collimating lens 230 comprises, illustratively, the optical axis 232. The laser beam 251 is collimated along the optical axis 232. The optical axis 232 is preferably arranged within specified tolerances in parallel to the longitudinal extension 201 of the laser module housing 210. An optical axis 232 in the context of the present disclosure is to be understood as a straight line through a center, in particular a center of curvature of an optical device, in this case the lens or the collimating lens 230.

According to FIG. 2, the laser unit 130 comprises a beam splitter 270 that divides the laser beam 251 emanating from the laser diode 135 into preferably two outgoing laser beams 252, 253. For this purpose, the laser diode 135 is arranged on an incoming side 271 of the beam splitter 270. The photodiode 260 is preferably arranged on an outgoing side 272 of the beam splitter 270. Preferably, the collimating lens 230 is arranged on a further outgoing side 273 of the beam splitter 270.

The laser module housing 210 preferably comprises a receptacle 211 that forms the laser diode holder 295 for receiving the laser diode 135 and the photodiode holder 265 for receiving the photodiode 260. Preferably, the receptacle 211 is arranged along a transverse direction 202 of the laser module housing 210 that is arranged perpendicularly to the longitudinal extension 201 of the laser module housing 210. Preferably, the beam splitter 270 is also arranged in the receptacle 211.

Illustratively, the laser diode 135 is arranged to the right of the beam splitter 270 and the photodiode 260 is illustratively arranged to the left of the beam splitter 270. Thus, the laser diode 135 and the photodiode 260 are illustratively arranged such that they are offset from each other by 180°, or are arranged oppositely on the beam splitter 270. The laser diode 135 can also be arranged illustratively to the left of the beam splitter 270 and the photodiode 260 can be arranged illustratively to the right of the beam splitter 270. Alternatively, the laser diode 135 and the photodiode 260 may also be arranged at a different angle with respect to each other, e.g., offset by 90° from each other.

The laser beam 251 is illustratively divided into an outgoing laser beam 252 directed to the photodiode 260 and an outgoing laser beam 253 directed to the collimating lens 230. The laser beam 253 is collimated or collected or bundled by the collimating lens 230 into a collimated laser beam 254. The beams of the laser beam 253 are substantially aligned in parallel by the collimating lens 230 so that they spread only minimally as they propagate.

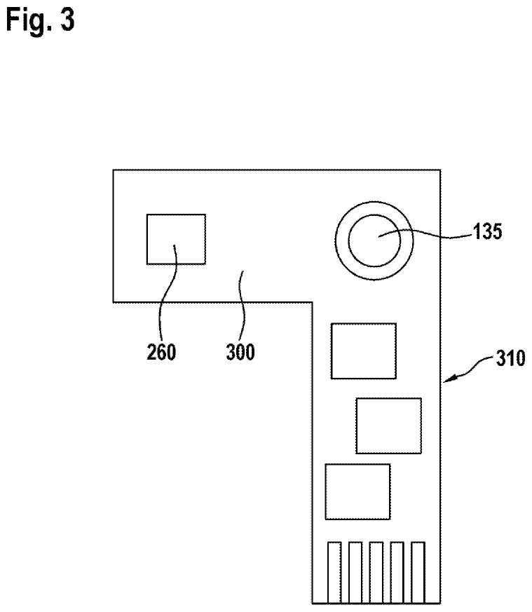

FIG. 3 shows a circuit board 300 associated with the laser unit 130 of FIG. 1 and FIG. 2. Preferably, the laser diode 135 of FIG. 1 and FIG. 2 and the photodiode 260 of FIG. 2 are arranged on the circuit board 300. Preferably, circuit parts 310 are arranged on the circuit board 300. Illustratively, three circuit parts 310 are arranged on the circuit board 300. It is noted, however, that the circuit board 300 may comprise any number of circuit parts 310.

According to one embodiment, the circuit board 300 is configured as a flexible and foldable circuit board. Sections of the circuit board 300 may be thereby arranged at specified angles or in parallel with one another.

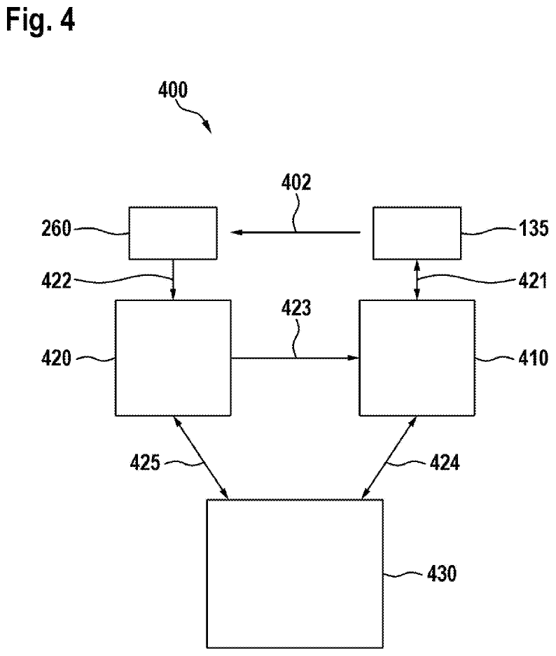

FIG. 4 shows a circuit 400 associated with the laser unit 130 of FIG. 1. The circuit 400 preferably comprises at least one automatic power control circuit 410 associated with the laser diode 135 and a protective circuit 420 associated with a corresponding photodiode, for example the photodiode 260 of FIG. 2.

The laser diode 135 is illustratively connected to the automatic power control circuit 410 via a connection 421. The automatic power control circuit 410 is preferably configured for automatically controlling a laser power of the laser diode 135, based on a measurement of the laser power by a monitor diode associated with the laser diode 135, e.g., the monitor diode 299 of FIG. 2. Preferably, the connection 421 is bidirectional. Such automatic power control circuit 410 is well known from the prior art and will therefore not be described in more detail. By way of example, the automatic power control circuit 410 is configured as an integral controller.

The laser beam transmitted by the laser diode 135 is also directed to the photodiode 260, which is visualized by an arrow 402. In a further configuration, the arrow 402 may also visualize or comprise scattered light. The photodiode 260 is preferably connected to the protective circuit 420 via a connection 422. Preferably, the connection 422 is unidirectional. Preferably, photocurrents determined by the photodiode 260 are passed through the connection 422 to the protective circuit 420.

The photodiode 260 is provided for a laser power measurement independent of the monitor diode 299 of FIG. 2, as described above. The protective circuit 420 is preferably connected to the automatic power control circuit 410 via a control line 423 and may disable the automatic power control circuit 410 via the control line 423 if the laser power measured by the photodiode 260 exceeds a specified laser power limit.

Moreover, preferably, further circuit parts 430 are connected to the protective circuit 420 via a connection 425. Preferably, the further circuit parts 430 are connected to the automatic power control circuit 410 via a connection 424. The further circuit parts 430 include, for example, a current/voltage supply and/or a control unit, in particular the electronic unit 190 of FIG. 1 of the rotary laser 100 of FIG. 1.

Preferably, the control of the laser power is based on a comparison of the laser power measured by the monitor diode 299 to a specified laser power setpoint. The laser power setpoint is less than the laser power limit for the protective circuit 420. For example, both the laser power setpoint and the laser power limit are configured by a control circuit associated with the circuit parts 430 and are preferably variable.

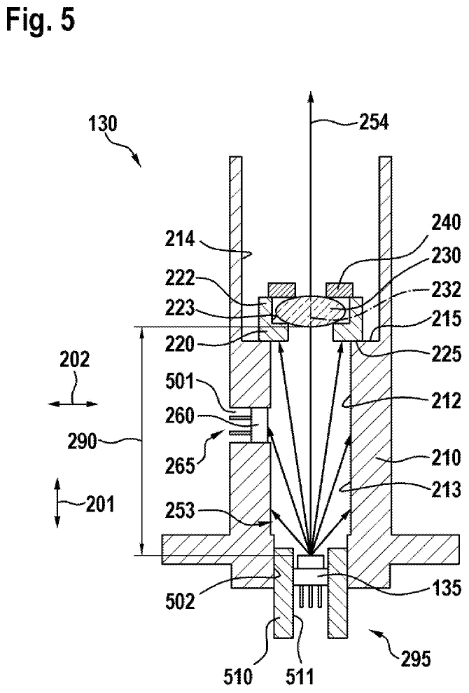

FIG. 5 shows an alternative configuration of the laser unit 130 of FIG. 1 with the laser diode 135, the photodiode 260, and the collimating lens 230. Analogously to FIG. 2, the collimating lens holder 220 is illustratively arranged in the upper receiving region 214 of the interior receptacle 212.

According to FIG. 5, the collimating lens holder 220 comprises only the upper section 222 of FIG. 2. Preferably, the underside 225 of the upper section 222 of the collimating lens holder 220 abuts the bottom surface 215 of the upper receptacle region 214. The collimating lens holder 220 is preferably fixedly, i.e., non-slidably, arranged in the interior receptacle 212.

The laser diode holder 295 of the laser diode 135 illustratively comprises a base body 510 with an interior receptacle 511, in which the laser diode 135 is arranged. Preferably, the laser diode holder 295 is arranged in a receptacle 502 of the laser module housing 210. The receptacle 502 is preferably arranged collinearly to the optical axis 232 of the collimating lens 230. A midpoint of the receptacle 502 is arranged on the optical axis 232. According to one embodiment, the laser diode holder 295 is slidably arranged along the longitudinal extension 201 of the laser module housing 210 in the receptacle 502 for adjusting the distance 290 between the laser diode 135 and the collimating lens 230.

Furthermore, by way of example, the laser module housing 210 comprises a receptacle 501 that is arranged within specified tolerances perpendicularly to the receptacle 502 of the laser diode holder 295. The receptacle 501 is illustratively arranged within specified tolerances perpendicularly to the interior receptacle 212 of the laser module housing 210. The receptacle 501 is illustratively formed in the lower section 213 of the interior receptacle 212 of the laser module housing 210. By way of example, the receptacle 501 forms the photodiode holder 265.

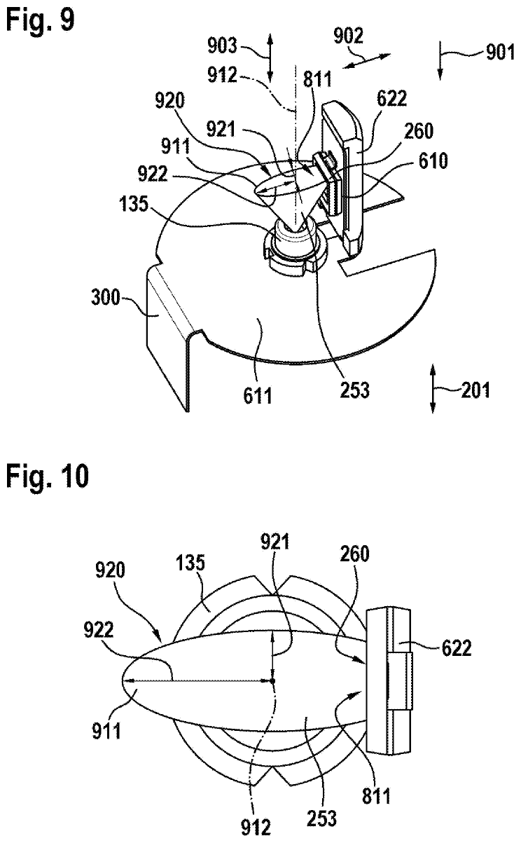

The receptacle 501, or photodiode holder 265, is illustratively arranged along the longitudinal extension 201 of the laser module housing 210 spaced apart from the receptacle 502 of the laser diode holder 295. The receptacle 501 is preferably arranged along a direction (922 in FIG. 9) of greatest divergence of an emission characteristic (911 in FIG. 9) of the laser diode 135. A photocurrent associated with the photodiode 260 preferably results from scattered light of the laser diode 135 due to divergence of the uncollimated laser beam 253 of the laser diode 135.

The laser diode 135 and the photodiode 260 may be arranged on separate circuit boards. The circuit boards are preferably configured as rigid or flexible circuit boards.

FIG. 6 illustrates another configuration of the laser unit 130 of FIG. 1, in which the laser diode 135 and the photodiode 260 are, by way of example, arranged on a common circuit board 300. Preferably, the circuit board 300 is configured as a flexible and foldable circuit board, as described above.

Illustratively, the circuit board 300 comprises at least a first circuit board section 611 and a second circuit board section 610. Preferably, the second circuit board section 610 is formed as a stamped-bent part. By way of example, the second circuit board section 610 is arranged approximately perpendicularly to the first circuit board section 611. Preferably, the first circuit board section 611 forms a bottom section 611, and the second circuit board section 610 forms a wall section 610. The laser diode 135 is preferably arranged on the first circuit board section 611, or the bottom section 611, and the photodiode 135 is arranged on the second circuit board section 610, or the wall section 610.

Preferably, a contacting element 625 is associated with the first circuit board section 611. The contacting element 625 serves to electrically contact the circuit board 300 with at least one power source.

The photodiode 260, in particular the second circuit board section 610, is preferably associated with a photodiode holder 622. The laser diode 135 is preferably associated with a laser diode holder 660. The laser diode holder 660 is provided for arranging the laser diode 135 in the laser module housing 210. Preferably, the laser diode holder 660 is arranged in an interior receptacle 643 of the laser module housing 210.

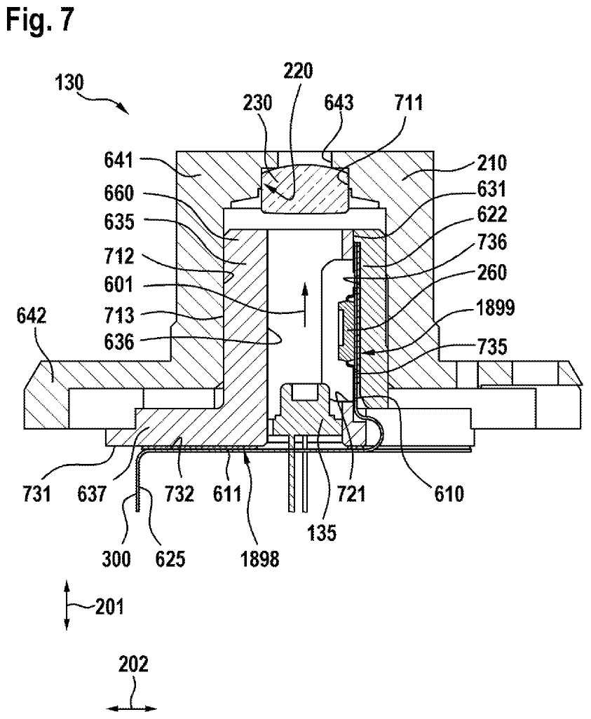

The laser diode holder 660 illustratively comprises a cylindrical base body 635 with an interior receptacle 636. Furthermore, the cylindrical base body 635 comprises, by way of example, a receptacle 631 with a recess (721 in FIG. 7) for arranging the photodiode 260 in the interior receptacle 636 of the laser diode holder 660. On its side facing away from the laser module housing 210, the laser diode holder 660 illustratively comprises a circumferential collar 637. The circumferential collar 637 comprises, by way of example, a recess 632 associated with the receptacle 631 and configured for arranging the photodiode holder 622 in the receptacle 631.

The laser module housing 210 preferably comprises a cylindrical base body 641 with the interior receptacle 643 for outputting the laser beam 254 of FIG. 2 and FIG. 5 generated and collimated by the laser diode 135. The interior receptacle 643 preferably assumes the function of the aperture 240 of FIG. 2. Preferably, the laser module housing 210 comprises a circumferential collar 642 facing the laser diode 135.

The flexible and foldable circuit board 300 is arranged, by way of example, on the laser diode holder 660. For this purpose, the first circuit board section 611 is preferably arranged on the circumferential collar 637, such that the laser diode 135 is arranged in the interior receptacle 636 of the laser diode holder 660. In the arrangement of the laser diode 135 in the interior receptacle 636, the second circuit board section 610 is arranged with the photodiode holder 622 not perpendicular to the first circuit board section 611. As a result, the second circuit board section 610 may be arranged, by way of bending through the recess 632, in the receptacle 631 of the laser diode holder 660. Preferably, the photodiode holder 622 is attached to the laser diode holder 660, preferably to the receptacle 631 of the laser diode holder 660. By way of bending, the second circuit board section 610 is arranged approximately perpendicularly to the first circuit board section 611 such that, analogously to FIG. 5, the photodiode 260 is arranged substantially perpendicularly to an emission direction 601 of a laser beam 253 of FIG. 2 and FIG. 5 of the laser diode 135.

Preferably, the collimating lens 230 is arranged and fixed in the interior receptacle 643 of the laser module housing 210. The laser diode holder 660 with the circuit board 300, the laser diode 135, and the photodiode 260 are also arranged in the interior receptacle 643. For example, the laser diode holder 660 is pressed into the interior receptacle 643 of the laser module housing 210.

FIG. 7 shows the laser unit 130 of FIG. 6 in the assembled state. The collimating lens 230 is preferably arranged in a receptacle section 711, shown as an upper section for illustrative purposes, of the interior receptacle 643 of the laser module housing 210 and is preferably fixed in place. The receptacle section 711 forms the collimating lens holder 220. The collimating lens 230 is preferably fixed in the interior receptacle 643, or the receptacle section 711, by way of a material bond, in particular an adhesive bond, and/or a press-connection.

Furthermore, as described above, the cylindrical base body 635 of the laser diode holder 660 is arranged in the interior receptacle 643, in particular in a receptacle section 712, shown as a lower section for illustrative purposes. Preferably, a press-connection is formed at least in sections between an outer circumference 713 of the cylindrical base body 635 and the receptacle section 712. Alternatively, the cylindrical base body 635 may be fixed in the interior receptacle 643 or the receptacle section 712 via a material bond.

Moreover, preferably, the first circuit board section 611 of the flexible and foldable circuit board 300 is fixed to the laser diode holder 660. Preferably, the first circuit board section 611 is fixed to the laser diode holder 660 by way of a material bond 1898. Preferably, the material bond 1898 is formed between a top surface 732 of the first circuit board section 611 of the flexible and foldable circuit board 300 facing the laser diode holder 660 and a bottom surface 731 of the circumferential collar 637 of the laser diode holder 660 facing the first circuit board section 611.

Furthermore, the second circuit board section 610 of the flexible and foldable circuit board 300 is preferably fixed to the photodiode holder 622 by way of a material bond 1899. In particular, a side 735 of the second circuit board section 610 facing away from the photodiode 260 is illustratively attached by way of the material bond 1899 to a side 736 of the photodiode holder 622 facing the second circuit board section 610. The photodiode holder 622 is preferably secured in the interior receptacle 643 by way of a press fit, preferably in receptacle section 712, shown as a lower section for illustrative purposes, of the laser module housing 210. According to one embodiment, at least one material bond 1898, 1899 is an adhesive bond.

Moreover, FIG. 7 visualizes the laser diode holder 660 with the cylindrical base body 635 with a receptacle 631 on its outer circumference. The receptacle 631 preferably comprises a recess 721 for arranging the photodiode 260 in the interior receptacle 636 of the laser diode holder 660. Preferably, the recess 721 is arranged within specified tolerances perpendicularly to the receptacle 631.

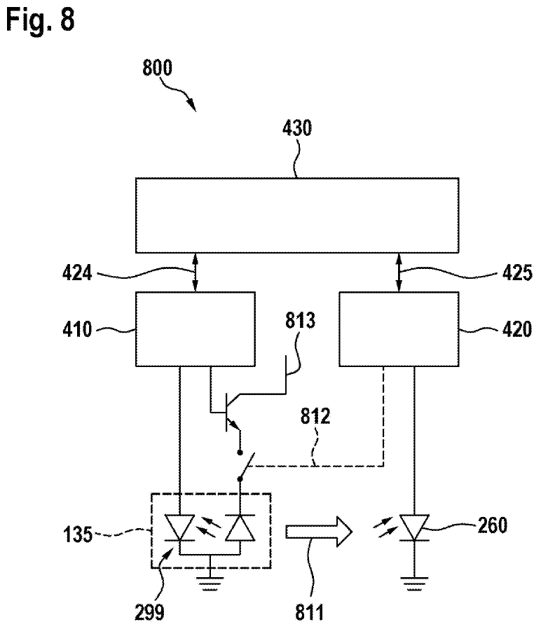

FIG. 8 shows an exemplary circuit 800 associated with the laser unit 130 of FIG. 2 or FIG. 5 to FIG. 7. The circuit 800, by way of example, analogously to the circuit 400 of FIG. 4, comprises the protective circuit 420 associated with the photodiode 260, which protective circuit is connected to further circuit parts 430 via the connection 425, as well as the automatic power control circuit 410 associated with the laser diode 135, which circuit is connected to the further circuit parts 430 via the connection 424. The further circuit parts 430 include, as described above, e.g., a current/voltage supply and/or a control unit, particularly the electronic unit 190 of FIG. 1 of the rotary laser 100 of FIG. 1.

The photodiode 260 is illustratively coupled to the laser diode 135 by scattered light 811 associated with the laser diode 135. Alternatively, an optical coupling via a beam splitter, e.g., the beam splitter 270 of FIG. 2, or the outgoing side 272 of the beam splitter 270 of FIG. 2. The automatic power control circuit 410 measures the laser power using the photocurrent of the monitor diode 299 integrated within the laser diode 135 and controls the supply of power to the laser diode 260. The protective circuit 420 measures the laser power by way of the photocurrent of the photodiode 260.

Preferably, the protective circuit 420 is configured to disable the laser diode 135 via a control line 812 by interrupting a power supply 813 associated with the laser diode 135 to the laser diode 135 if the laser power measured by the photodiode 260 exceeds a specified laser power limit. Alternatively, the protective circuit 420 disables the automatic power control circuit 410 via an associated control line, as described in FIG. 4.

FIG. 9 illustrates the flexible and foldable circuit board 300 of FIG. 6 and FIG. 7 with the first circuit board section 611, on which the laser diode 135 is arranged, and with the second circuit board section 610 illustratively arranged perpendicularly to the first circuit board section 611 with the photodiode 260 and the photodiode holder 622. Preferably, the laser diode 135 has an emission characteristic 911 with a divergence, i.e., an expansion of the laser beam 253 over a certain distance, which has an elliptical cross-section 920. The divergence of the laser beam 253 emitted by the laser diode 135 is preferably formed perpendicularly to an optical axis 912 of the laser beam 253.

Due to the elliptical cross-section, the divergence preferably has a comparatively small value in a first direction 921 that is perpendicular to the optical axis 912, and, in a second direction 922 that is arranged perpendicularly to the optical axis 912 and perpendicularly to the first direction 921, the divergence preferably has a comparatively large value. Therefore, in order to achieve as good a coupling of the scattered light 811 into the photodiode 260 as possible, the photodiode 260 is preferably positioned substantially/approximately along the direction 922 of the greatest divergence relative to the laser diode 135.

Knowing the divergence of the laser diode 135, a suitable position of the photodiode 260 relative to the optical axis 912 of the laser beam 253 of the laser diode 135 in radial direction 902 and axial direction 903 may be determined, which enables a laser power measurement by the protective circuit 420 with a sufficient signal-to-noise ratio, while at the same time excluding a shading by the photodiode 260 of the optical path between the laser diode 135 and the collimating lens 230 in FIG. 5 to FIG. 7.

FIG. 10 shows the arrangement of the photodiode 260 in relation to the laser diode 135 when viewed in the direction of an arrow 901 of FIG. 9, to illustrate the emission characteristic 911 of the laser diode 135. This illustrates the elliptical cross-section 920 as well as the first direction 921, preferably associated with least divergence, and the second direction 922, preferably associated with greatest divergence. As described above, the photodiode 260 is preferably arranged substantially/approximately in the direction 922 of greatest divergence.

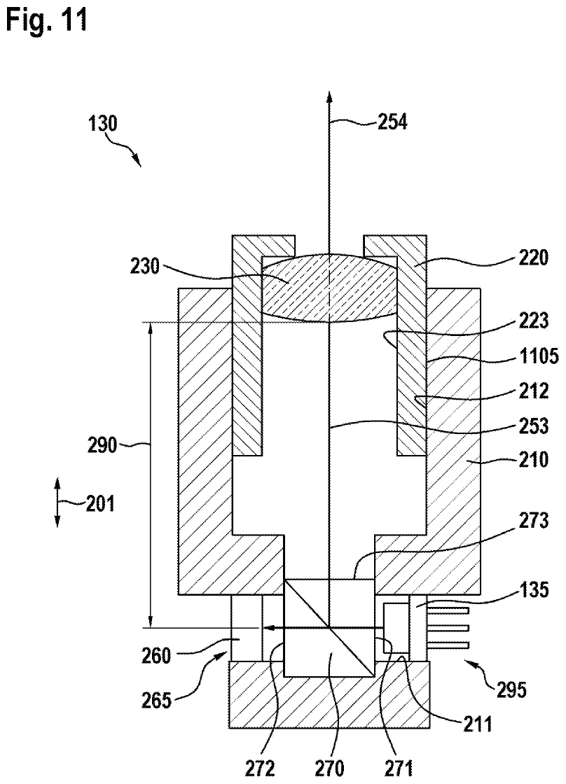

FIG. 11 shows the laser unit 130 of FIG. 2 with an alternative configuration of the collimating lens holder 220. The collimating lens holder 220 preferably comprises only the lens receptacle 223, in which the collimating lens 230 is arranged. An outer circumference 1105 of the collimating lens holder 220 is preferably arranged in the interior receptacle 212 of the laser module housing 210. In this respect, the collimating lens holder 220 is illustratively slidably arranged in the interior receptacle 212 of the laser module housing 210 along the longitudinal extension 201 of the laser module housing 210 for adjusting the distance 290 between the laser diode 135 and the collimating lens 230 in the interior receptacle 212.

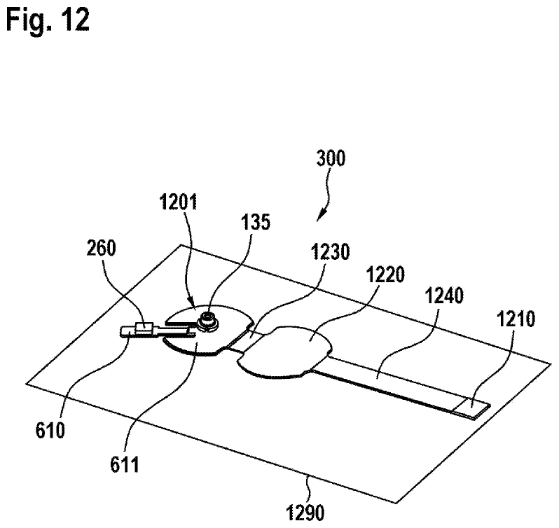

FIG. 12 shows the flexible and foldable circuit board 300 of FIG. 3 in the unfolded state with the first circuit board section 611, on which the laser diode 135 is arranged, and the second circuit board section 610 with the photodiode 260, viewed from a top side 1201 of the circuit board 300. The second circuit board section 610 is illustratively arranged in a common plane 1290 with the first circuit board section 611.

Illustratively, a third circuit board section 1220, which can be arranged in parallel with the first circuit board section 611, is provided. Illustratively, the third circuit board section 1220 is also arranged in the plane 1290. The third circuit board section 1220 is preferably connected to the first circuit board section 611 via a connecting section 1230.

Preferably, the first circuit board section 611 or the third circuit board section 1220 is connected to a contacting element 1210 via a flexible connecting section 1240. Illustratively, the third circuit board section 1220 is connected to the contacting element 1210 via the flexible connecting section 1240. The contacting element 1210 is preferably formed only on the top side 1201 of the circuit board 300.

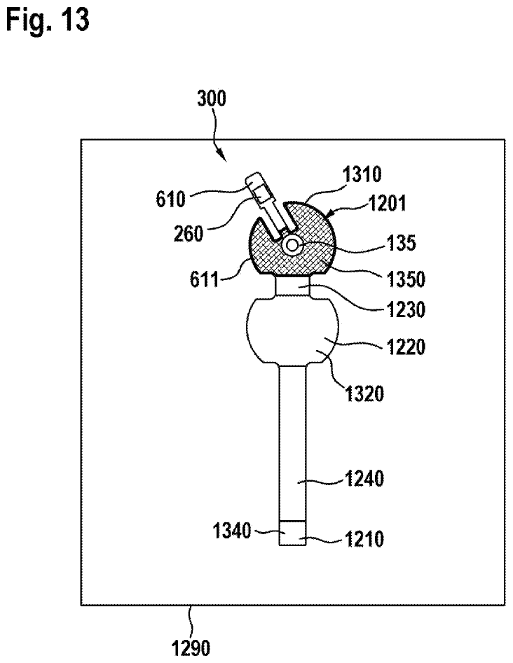

FIG. 13 shows the flexible and foldable circuit board 300 of FIG. 12 viewed in the plane 1290 from the top side 1201. Preferably, the first circuit board section 611, the third circuit board section 1220, and/or the contacting element 1210 comprise reinforcing elements 1310, 1320, 1340. Illustratively, a reinforcing element 1310 is associated with the first circuit board section 611, a reinforcing element 1320 is associated with the third circuit board section 1220, and a reinforcing element 1340 is associated with the contacting element 1210.

By way of example, the first circuit board section 611 is associated at least in sections with a fixing element 1350 for forming the material bond 1898 with the laser diode holder 660 of FIG. 6 and FIG. 7. Preferably, the fixing element 1350 is double-sided adhesive tape.

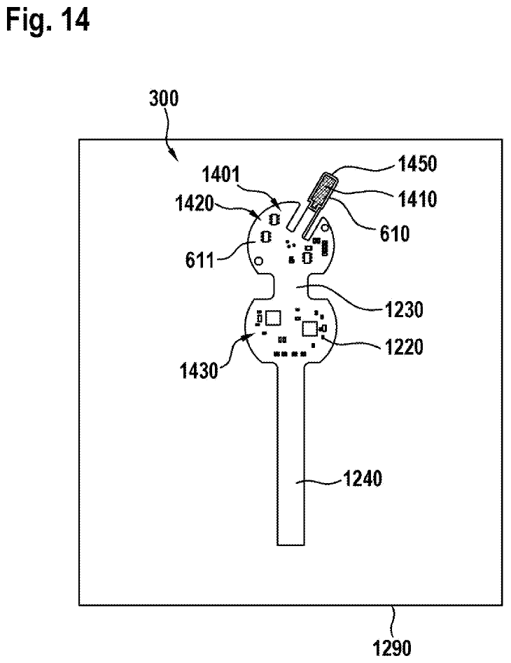

FIG. 14 shows the flexible and foldable circuit board 300 of FIG. 12 and FIG. 13 viewed in the plane 1290 from a bottom side 1401 opposite the top side 1201 of FIG. 12 and FIG. 13. The first circuit board section 611 and/or the third circuit board section 1220 preferably have electrical components 1420, 1430 on the bottom side 1401. Illustratively, the electrical components 1420 are associated with the first circuit board section 611, and the electrical components 1430 are associated with the third circuit board section 1220.

Preferably, a reinforcing element 1450 is associated with the second circuit board section 610. Preferably, a fixing element 1410 for forming the material bond 1899 with the photodiode holder 622 of FIG. 6 and FIG. 7 is associated at least sections with the second circuit board section 610. Preferably, the fixing element 1410 is double-sided adhesive tape.

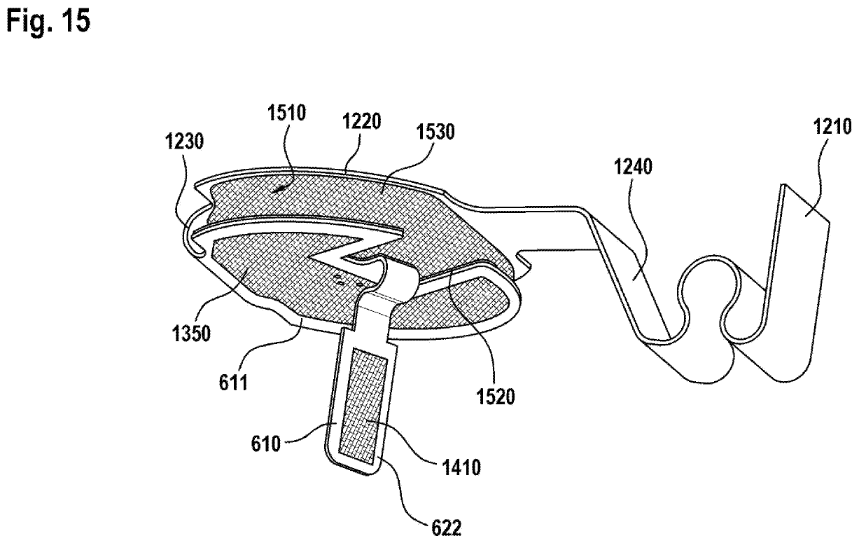

FIG. 15 shows the flexible and foldable circuit board 300 of FIG. 12 to FIG. 14 in the folded state, in which the second circuit board section 610 is arranged at least approximately perpendicularly to the first circuit board section 611, and the third circuit board section 1220 is arranged at least approximately in parallel to the first circuit board section 611. Furthermore, the flexible connecting section 1240 is illustratively folded. FIG. 15 illustrates the fixing element 1350 associated with the first circuit board section 611 and the fixing element 1410 associated with the second circuit board section 610.

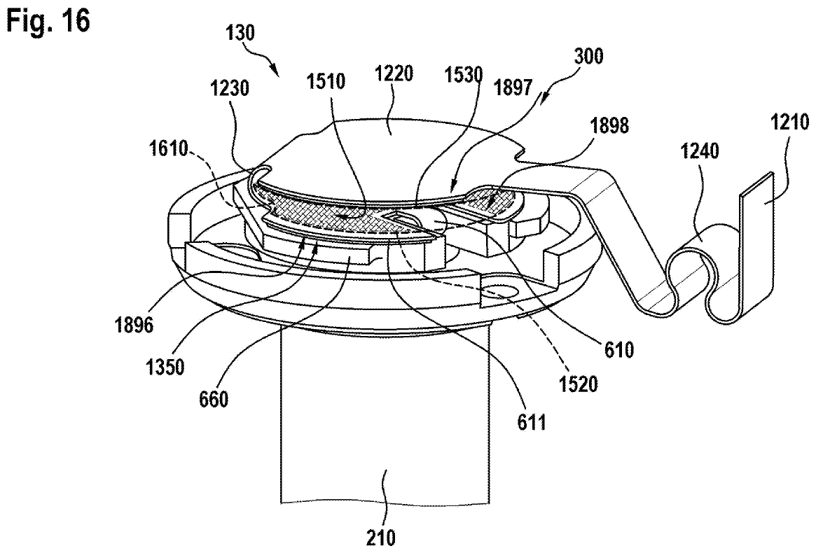

Preferably, the first and third circuit board sections 611, 1220 form a receptacle 1510. Preferably, the receptacle 1510 is configured in the manner of a sandwich. Preferably, in the receptacle 1510, a spacer element (1610 in FIG. 16) can be arranged. By way of example, the first and/or third circuit board section 611, 1220 is at least partially associated with a fixing element 1520, 1530 for forming a material bond (1896, 1897 in FIG. 16).

FIG. 16 shows the laser unit 130 of FIG. 6 and FIG. 7 with the flexible and foldable circuit board 300 of FIG. 12 to FIG. 15. A spacer element 1610 is arranged in the receptacle 1510 formed between the first and third circuit board sections 611, 1220. By way of the spacer element 1610, in particular by a sufficient thickness of the spacer element 1610, a bending radius of the connecting section 1230 of the circuit board 300 can be controlled. Furthermore, the spacer element 1610 serves as electrical insulation to prevent a short circuit between the first and third circuit board sections 611, 1220. The components 1420, 1430 arranged on the first and/or third circuit board sections 611, 1220 are thus also mechanically protected.

The spacer element 1610 is preferably fixed to the first circuit board section 611 and/or the third circuit board section 1220 by way of a material bond 1897, 1896. Preferably, the material bonds 1897, 1896 are adhesive bonds, wherein the fixing element 1520 associated with the first circuit board section 611 and/or the fixing element 1530 associated with the third circuit board section 1220 form the respective adhesive bond 1896, 1897 with the spacer element 1610. Preferably, the spacer element 1610 is comprised of a non-electrically conductive material.

Preferably, the spacer element 1610 is comprised of a soft material. By way of example, the spacer element 1610 is comprised of foam, rubber, or felt. Alternatively, the spacer element 1610 is an injection molded part.

Furthermore, FIG. 16 illustrates the material bond 1898 between the first circuit board section 611 and the laser diode holder 660 by way of the exemplary fixing element 1350.

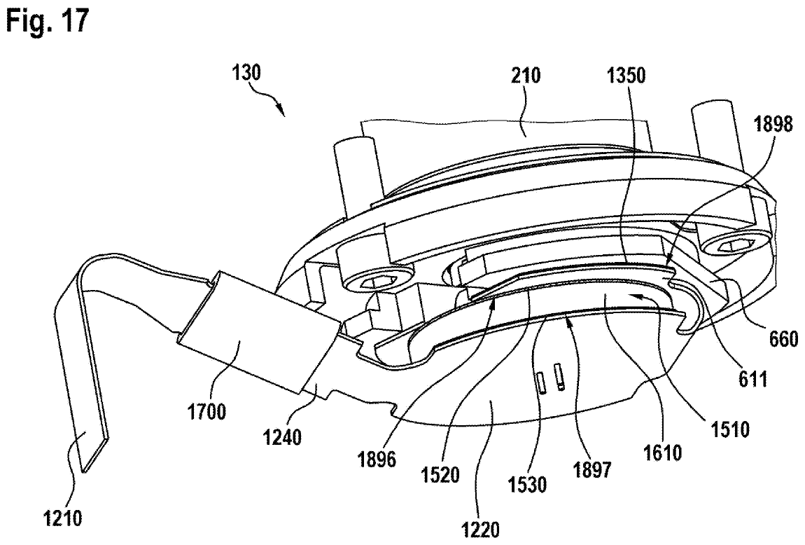

FIG. 17 shows the laser unit 130 of FIG. 16. Illustratively, the flexible and foldable circuit board 300 is associated with a shielding element 1700. Preferably, the shielding element 1700 is fixed to the flexible and foldable circuit board 300 by way of a material bond, a latch connection, and/or a press-connection. Preferably, the shielding element 1700 is arranged on the flexible connecting section 1240.

Preferably, the shielding element 1700 is comprised of ferrite. The shielding element 1700 is configured to improve electromagnetic compatibility (EMC) of the laser unit 130.

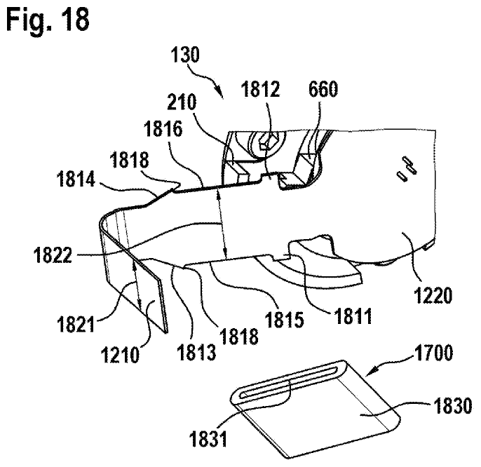

FIG. 18 shows the laser unit 130 of FIG. 17, wherein the shielding element 1700 is illustratively arranged adjacent to the flexible connecting section 1240. Preferably, the flexible and foldable circuit board 300 comprises a receiving area 1815, 1816, preferably bounded by lateral bars 1811, 1812, 1813, 1814. By way of example, the shielding element 1700 comprises an interior receptacle 1831 for arrangement in the receiving area 1815, 1816 of the flexible and foldable circuit board 300.

Illustratively, the contacting element 1210 has a width 1821, which widens over at least one ramp-like bar 1813, 1814, illustratively over two opposing ramp-like bars 1813, 1814, into a width 1822 of the receiving area 1815, 1816. The two ramp-like bars 1813, 1814 preferably form a detent function with adjoining edges 1818. The adjoining edges 1818 preferably prevent the shielding element 1700 from slipping away from the receiving area 1815, 1816 of the circuit board 300.

Preferably, at least one bar, illustratively the bars 1811, 1812, is configured in the manner of a protrusion and thereby forms a stop function. The bars 1811, 1812, 1813, 1814 preferably have a width that is wider than the width 1822 formed between the receiving regions 1815, 1816. Alternatively or optionally, between the receiving region 1815, 1816 and the interior receptacle 1831 of the shielding element 1700, a press fit is formed due to an oversize of the receiving region 1815, 1816.

The shielding element 1700 is preferably pushed onto the circuit board 300 during assembly in the area of the contact element 1210 and arranged over the ramp-like bars 1813, 1814 in the receiving area 1815, 1816.

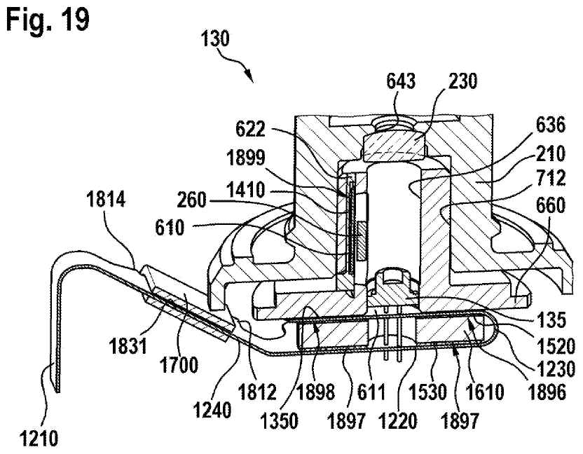

FIG. 19 shows the laser unit 130 of FIG. 17 and FIG. 18 with the shielding element 1700 on the flexible connecting section 1240 of the flexible and foldable circuit board 300. Furthermore, FIG. 19 illustrates the material bonds 1896, 1897, 1898, 1899, which are exemplarily formed in each case by way of fixing elements, in particular adhesive elements 1520, 1530, 1350, 1410. Preferably, the fixing elements 1520, 1530, 1350, 1410 are formed as adhesive elements. It is noted that the material bonds 1896, 1897, 1898, 1899 may also be configured as solder connections or the like.

Alternatively, the flexible and foldable circuit board 300, or the first circuit board section 611, is attached at the first circuit board section 611 to the laser diode holder 660 by way of a soldered connection of the laser diode 135 pressed into the laser diode holder 660.

What is claimed is:

1. A laser unit for a rotary laser, comprising:
a laser module housing;
a laser diode arranged in the housing and configured to generate a laser beam, wherein the laser diode is associated with a monitor diode;
a collimating lens arranged in the housing and configured to collimate the laser beam;
an automatic power control circuit configured to automatically control a laser power of the laser diode based on a measurement of the laser power by the monitor diode; and
a photodiode configured for a laser power measurement independent of the monitor diode.

2. The laser unit according to claim 1, wherein the monitor diode is integrated into the laser diode.

3. The laser unit according to claim 1, wherein the photodiode is associated with a protective circuit, which is configured to disable the laser diode via a control line by interrupting a power supply to the laser diode, or to disable the automatic power control circuit via a control line, if the laser power measured by the photodiode exceeds a specified laser power limit.

4. The laser unit according to claim 1, wherein the laser diode is associated with a laser diode holder, the photodiode is associated with a photodiode holder, and/or the collimating lens is associated with a collimating lens holder.

5. The laser unit according to claim 4, wherein the laser module housing includes a receptacle configured to form the laser diode holder for receiving the laser diode and the photodiode holder for receiving the photodiode, wherein a beam splitter is arranged in the receptacle, and wherein the laser diode is arranged on an incoming side of the beam splitter and the photodiode is arranged on an outgoing side of the beam splitter.

6. The laser unit according to claim 5, wherein the collimating lens is arranged on a further outgoing side of the beam splitter.

7. The laser unit according to claim 4, wherein:
the laser module housing includes a first receptacle configured as a photodiode holder for receiving the photodiode, and a second receptacle configured as a laser diode holder for receiving the laser diode,
the first receptacle is arranged perpendicularly to the second receptacle, and
the second receptacle is arranged collinearly to an optical axis of the collimating lens.

8. The laser unit according to claim 7, wherein the first receptacle is arranged spaced apart from the second receptacle along a longitudinal extension of the laser module housing.

9. The laser unit according to claim 7, wherein the first receptacle is arranged along a direction of greatest divergence of an emission characteristic of the laser diode.

10. The laser unit according to claim 4, further comprising a circuit board on which the laser diode and the photodiode are arranged, wherein:
the circuit board and the photodiode holder are arranged on the laser diode holder.

11. The laser unit according to claim 10, wherein:
the circuit board includes at least a first circuit board section and a second circuit board section arranged perpendicularly or in parallel to the first circuit board section, and
the laser diode is arranged at the first circuit board section and the photodiode is arranged on the second circuit board section.

12. The laser unit according to claim 10, wherein the circuit board is configured as a flexible circuit board.

13. The laser unit according to claim 4, wherein the laser module housing includes a receptacle configured to form the collimating lens holder.

14. The laser unit according to claim 4, wherein a distance between the laser diode and the collimating lens is variable, wherein the laser diode holder of the laser diode is slidably arranged in a receptacle of the laser module housing along the longitudinal extension of the laser module housing, and/or the collimating lens holder of the collimating lens is slidably arranged in an interior receptacle of the laser module housing along the longitudinal extension of the laser module housing, and wherein the interior receptacle is arranged collinearly to an optical axis of the collimating lens.

15. A rotary laser comprising the laser unit according to claim 1.
